(19) United States
(12) Patent Application Publication
(10) Pub. No.: US 2024/0311534 A1
(43) Pub. Date: Sep. 19, 2024

(54) METHOD AND SYSTEM FOR SIMULATING WATER-INDUCED ROCK STRENGTH DETERIORATION BASED ON DISCRETE ELEMENT METHOD

(71) Applicant: INSTITUTE OF GEOLOGY AND GEOPHYSICS, CAS, Beijing (CN)

(72) Inventors: Lei XUE, Beijing (CN); Fengchang BU, Beijing (CN); Chao XU, Beijing (CN); Yuan CUI, Beijing (CN); Mengyang ZHAI, Beijing (CN); Haoyu WANG, Beijing (CN)

(73) Assignee: INSTITUTE OF GEOLOGY AND GEOPHYSICS, CAS, Beijing (CN)

(21) Appl. No.: 18/224,660

(22) Filed: Jul. 21, 2023

(30) Foreign Application Priority Data
Mar. 16, 2023 (CN) 202310250468.5

(51) Int. Cl. G06F 30/28

(52) U.S. Cl. CPC G06F 30/28

(57) ABSTRACT

The present disclosure relates to a method and system for simulating water-induced rock strength deterioration based on a discrete element method, and relates to the field of simulation of water-induced rock strength deterioration. The method includes: determining mineral type and content information and simulation block parameters of a rock sample; preparing rock samples with different saturations; determining macro-mechanical parameters of the rock samples; calibrating the parameters; setting gradients for calibrated parameters; determining Young's moduli, uniaxial compressive strength, Brazilian tensile strength, contact cohesion and contact internal friction angles of a numerical model under different contact normal stiffness, different contact cohesion, different contact internal friction angles and different contact tensile strength; determining a relationship between various simulation parameters and macro-mechanical parameters obtained by simulation; determining predicted values of the simulation parameters; determining macro-mechanical parameters of the numerical model; and finely adjusting the predicted values of the simulation parameters.

### CROSS REFERENCE TO RELATED APPLICATION

This patent application claims the benefit and priority of Chinese Patent Application No. 202310250468.5, filed with the China National Intellectual Property Administration on Mar. 16, 2023, the disclosure of which is incorporated by reference herein in its entirety as part of the present application.

### TECHNICAL FIELD

The present disclosure relates to the field of simulation of water-induced rock strength deterioration, and in particular, to a method and system for simulating water-induced rock strength deterioration based on a discrete element method.

### BACKGROUND

It is one of main reasons of engineering geological disasters of rock mass that the rock softens when soaked in water, thereby reducing strength and is more prone to deformation and failure. Based on structural characteristics of rock mass, numerical simulation can reproduce a response process of rock mass engineering geological body under the action of internal and external factors, thereby providing an important basis for the prevention and control of rock mass engineering geological disasters. Therefore, implementing numerical simulation of water-induced rock strength deterioration is of great significance for rock mass engineering practice.

Among many numerical simulation means, a discrete element method can simulate nonlinear large deformation characteristics of jointed rock mass more truly, and is widely favored by rock mass engineering practitioners. In the discrete element method, a discontinuous medium such as rock mass is composed of rigid bodies or deformable particles, and the particles are bonded by contact. By defining properties and constitutive equations of particles and contact, a user can solve physical quantities such as force and relative displacement, calculate behaviors such as translation and rotation of particles and contact-related separation, slip and compression, so as to implement nonlinear mechanical behavior simulation of rock mass, and thus the method is widely used in numerical simulation of landslides, mining, bridges and tunnels, etc.

Thanks to the remarkable advantages of the discrete element method in simulating mechanical behavior of rock mass, some methods for simulating water-induced rock strength deterioration based on the discrete element method have emerged, and may fall into three categories according to their principles:

(1) It is assumed that simulation parameters are equivalent to macro-mechanical parameters of rocks (Wang et al., 2019). Results of many rock water absorption tests show that the water-induced rock strength deterioration is reflected in the decrease of macro-mechanical parameters of rock, specifically including decrease of an internal friction angle, cohesion, Young's modulus and uniaxial compressive strength with the increase of rock saturation. By assuming that the simulation parameters are equivalent to the above macro-mechanical parameters of rock, a relationship between the simulation parameters and saturation can be obtained according to results of a water absorption test, so as to implement simulation of water-induced rock strength deterioration. However, there are obvious differences between the simulation parameters and macro-mechanical parameters of rocks in physical meaning and scale, so the equivalence between the simulation parameters and the macro-mechanical parameters of rocks is wrong in principle.

(2) A water-induced rock strength deterioration mechanism (Gu et al., 2020) is simulated. Previous studies have shown that the water-induced rock strength deterioration is due to dissolution of cement in rock under mechanical, chemical and physical effects of water-rock contact. With the help of the basic principle of the discrete element method, the simulation of water-induced rock strength deterioration can be implemented by assuming that parameters of contact between particles decrease after encountering with water, specifically including decrease of contact stiffness, a contact internal friction angle, contact tensile strength and contact cohesion with the increase of saturation. However, numerical simulation parameters are constrained by the macro-mechanical parameters of rocks rather than saturation. This basic principle is ignored in directly constructing a relationship between the numerical simulation parameters and the saturation, resulting in poor authenticity of results obtained.

(3) Simulation parameters are calibrated according to macro-mechanical parameters of rocks with different saturations (Luo Zuosen et al., 2019). According to the principle that simulation parameters in the discrete element method are constrained by macro-mechanical parameters of rocks, simulation parameters, including an elastic modulus of blocks, a Poisson's ratio of blocks, contact stiffness, a contact internal friction angle, contact tensile strength, contact cohesion, etc., can be continuously adjusted by means of a conventional trial and error method with macro-mechanical parameters of rocks with different saturations as conditions, until simulation results are consistent with test results of each group, and finally each group of simulation parameters is determined, thereby representing mechanical behavior of rocks with different saturations. This method requires continuous trial and error of simulation parameters, which greatly occupies computational resources.

In view of the problems of unclear principle, poor authenticity and complicated calculation in a conventional method for simulating water-induced rock strength deterioration, the present disclosure aims to propose a novel method and system for simulating water-induced rock strength deterioration based on a discrete element method, to simply and practically implement numerical simulation representation of water-induced rock strength deterioration.

### SUMMARY

An objective of the present disclosure is to provide a method and system for simulating water-induced rock strength deterioration based on a discrete element method, to implement numerical simulation representation of water-induced rock strength deterioration, and improve simulation precision and calculation efficiency.

To achieve the above objective, the present disclosure provides the following solutions:

According to a first aspect, the present disclosure provides a method for simulating water-induced rock strength deterioration based on a discrete element method, including:
S1: determining mineral type and content information of rock samples by using an X-ray diffractometer;
S2: determining simulation block parameters according to the mineral type and content information of the rock sample, where the simulation block parameter includes a simulation block density ρ, a simulation block bulk modulus K^{block}, and a simulation block shear modulus G^{block},
S3: preparing rock samples with different saturations;
S4: performing a uniaxial compression test, a Brazilian split test and a triaxial compression test on the rock samples with the different saturations by using a servo rigidity testing machine to obtain macro-mechanical parameters of the rock samples with the different saturations, where the macro-mechanical parameter includes a Young's modulus E, a Poisson's ratio μ, a shear modulus G, uniaxial compressive strength (UCS), Brazilian tensile strength (BTS), cohesion c, and an internal friction angle
S5: selecting a group of macro-mechanical parameters of a rock sample with any saturation, and calibrating simulation parameters corresponding to the macro-mechanical parameters of the rock sample with the saturation based on the simulation block parameters, where the simulation parameter includes contact normal stiffness kₙ, contact shear stiffness kₛ, contact cohesion c^{cont}, a contact internal friction angle ϕ^{cont}, and contact tensile strength σₜ^{cont}.
S6: setting gradients for calibrated contact normal stiffness kₙ, contact cohesion c^{cont}, contact internal friction angle ϕ^{cont} and contact tensile strength σₜ^{cont}, respectively;
S7: performing uniaxial compression numerical simulation, Brazilian split numerical simulation and triaxial compression numerical simulation respectively by using different contact normal stiffness kₙ, different contact cohesion c^{cont}, different contact internal friction angles ϕ^{cont} and different contact tensile strength σₜ^{cont}, so as to obtain Young's moduli E, uniaxial compressive strength (UCS), Brazilian tensile strength (BTS), cohesion c and internal friction angles ϕ of a numerical model under the different contact normal stiffness kₙ, the different contact cohesion c^{cont}, the different contact internal friction angles ϕ^{cont} and the different contact tensile strength σₜ^{cont};
S8: obtaining, through linear fitting, a relationship between various simulation parameters and macro-mechanical parameters obtained by simulation;
S9: inputting the macro-mechanical parameters of actual rocks with the different saturations obtained in step S4 into the relationship between the various simulation parameters and the macro-mechanical parameters of the numerical model to obtain predicted values of the simulation parameters under the different saturations;
S10: performing uniaxial compression numerical simulation, Brazilian split numerical simulation and triaxial compression numerical simulation in discrete element method software with the predicted values of the simulation parameters under the different saturations obtained in step S9 as inputs, to obtain macro-mechanical parameters of the numerical model;
S11: comparing the macro-mechanical parameters of the numerical model with the macro-mechanical parameters of the rock sample to obtain a comparison result;
S12: finely adjusting the predicted values of the simulation parameters under the different saturations according to the comparison result, until the obtained macro-mechanical parameters of the numerical model are the same as the macro-mechanical parameters of the actual rocks; and
S13: simulating rock working conditions under the different saturations based on the finely-adjusted predicted values of the simulation parameters under the different saturations, where the finely-adjusted predicted values of the simulation parameters under the different saturations are final values.

Optionally, the selecting a group of macro-mechanical parameters of a rock sample with any saturation, and calibrating simulation parameters corresponding to the macro-mechanical parameters of the rock sample with the saturation based on the simulation block parameters specifically includes the following steps:
S5.1: inputting any group of simulation parameters, including contact normal stiffness kₙ, contact shear stiffness kₛ, contact cohesion c^{cont}, a contact internal friction angle ϕ^{cont}, and contact tensile strength σₜ^{cont}.
S5.2: determining whether the contact normal stiffness and the contact shear stiffness are less than or equal to a preset threshold;
S5.3: if no, returning to step S5.1;
S5.4: if yes, performing a next step;
S5.5: determining whether a ratio of the contact shear stiffness to the contact normal stiffness is equal to a ratio of a sample shear modulus to a sample Young's modulus;
S5.6: if no, returning to step S5.1;
S5.7: if yes, performing a next step;
S5.8: performing the uniaxial compression numerical simulation in the discrete element method software, where dimension and boundary conditions of the numerical model are the same as those of uniaxially compressed samples and loading conditions;
S5.9: determining whether the Young's modulus of the numerical model obtained by the uniaxial compression numerical simulation is equal to a test value;
S5.10: if no, returning to step S5.1;
S5.11: if yes, determining values of the contact shear stiffness and the contact normal stiffness, still keeping the values of the contact shear stiffness and the contact normal stiffness unchanged even after returning to step S5.1 in subsequent steps, and performing a next step;
S5.12: performing the Brazilian split numerical simulation in the discrete element method software, where dimension and boundary conditions of the numerical model are the same as those of Brazilian split samples and loading conditions;
S5.13: determining whether the Brazilian tensile strength of the numerical model obtained by the Brazilian split numerical simulation is equal to a test value;
S5.14: if no, returning to step S5.1;
S5.15: if yes, determining a value of the contact tensile strength, still keeping the value of the contact tensile strength unchanged even after returning to step S5.1 in subsequent steps, and performing a next step;
S5.16: performing the uniaxial compression numerical simulation and the triaxial compression numerical simulation in the discrete element method software, where dimension and boundary conditions of the numerical model are the same as those of samples for the uniaxial compression test and the triaxial compression test and loading conditions;
S5.17: determining whether the cohesion and the internal friction angle of the numerical model obtained by the uniaxial compression numerical simulation and the triaxial compression numerical simulation are equal to test values;
S5.18: if no, returning to step S5.1;
S5.19: if yes, determining the contact cohesion and the contact internal friction angle, and ending a trial and error method, thereby completing the calibration of the simulation parameters used to simulate mechanical behavior of samples under a selected saturation.

Optionally, the preparing rock samples with different saturations specifically includes:
preparing saturated rock samples according to international standards, preparing dry rock samples by using a drying oven, and causing the dry rock samples to absorb water by using a quality control method in a vacuum container, so as to obtain the rock samples with the different saturations.

Optionally, a simulation block represents mineral particles.

Optionally, an expression of the preset threshold is as follows:

$$10 max \frac{{K}^{block} + \frac{4}{3 {G}^{block}}}{Δ {z}_{min}}$$

where Δzₘᵢₙ represents a minimum width of adjacent elements in a vertical direction, max represents a maximum value of all elements contact-adjacent to each other, K^{block} represents a simulation block bulk modulus, and G^{block} represents a simulation block shear modulus.

Optionally, the relationship between the various simulation parameters and the macro-mechanical parameters obtained by simulation specifically includes: a contact normal stiffness—Young's modulus relationship, a contact tensile strength—Brazilian tensile strength relationship, a contact cohesion—uniaxial compressive strength relationship, a contact cohesion-cohesion relationship, a contact internal friction angle—uniaxial compressive strength relationship, and a contact internal friction angle—internal friction angle relationship.

According to a second aspect, based on the above method of the present disclosure, the present disclosure additionally provides a system for simulating water-induced rock strength deterioration based on a discrete element method, including:
a module for determining mineral type and content information of rock samples, configured to determine mineral type and content information of rock samples by using an X-ray diffractometer;
a simulation block parameter determining module, configured to determine simulation block parameters according to the mineral type and content information of the rock sample, where the simulation block parameter includes a simulation block density ρ, a simulation block bulk modulus K^{block}, and a simulation block shear modulus G^{block},
a module for preparing rock samples with different saturations, configured to prepare rock samples with different saturations;
a module for determining macro-mechanical parameters of rock samples with different saturations, configured to perform a uniaxial compression test, a Brazilian split test and a triaxial compression test on the rock samples with the different saturations by using a servo rigidity testing machine to obtain macro-mechanical parameters of the rock samples with the different saturations, where the macro-mechanical parameter includes a Young's modulus E, a Poisson's ratio μ, a shear modulus G, uniaxial compressive strength (UCS), Brazilian tensile strength (BTS), cohesion c, and an internal friction angle ϕ;
a calibration module, configured to select a group of macro-mechanical parameters of a rock sample with any saturation, and calibrate simulation parameters corresponding to the macro-mechanical parameters of the rock sample with the saturation based on the simulation block parameters, where the simulation parameter includes contact normal stiffness kₙ, contact shear stiffness kₛ, contact cohesion c^{cont}, a contact internal friction angle ϕ^{cont}, and contact tensile strength σₜ^{cont}.
a gradient setting module, configured to set gradients for calibrated contact normal stiffness kₙ, contact cohesion c^{cont}, contact internal friction angle ϕ^{cont} and contact tensile strength σₜ^{cont}, respectively;
a first numerical simulation module, configured to perform uniaxial compression numerical simulation, Brazilian split numerical simulation and triaxial compression numerical simulation respectively by using different contact normal stiffness kₙ, different contact cohesion c^{cont}, different contact internal friction angles ϕ^{cont} and different contact tensile strength σₜ^{cont}, so as to obtain Young's moduli E, uniaxial compressive strength (UCS), Brazilian tensile strength (BTS), cohesion c and internal friction angles ϕ of a numerical model under the different contact normal stiffness kₙ, the different contact cohesion c^{cont}, the different contact internal friction angles ϕ^{cont} and the different contact tensile strength σₜ^{cont},
a linear fitting module, configured to obtain, through linear fitting, a relationship between various simulation parameters and macro-mechanical parameters obtained by simulation;
a prediction module, configured to input the macro-mechanical parameters of actual rocks with the different saturations into the relationship between the various simulation parameters and the macro-mechanical parameters of the numerical model to obtain predicted values of the simulation parameters under the different saturations;
a second numerical simulation module, configured to perform uniaxial compression numerical simulation, Brazilian split numerical simulation and triaxial compression numerical simulation in discrete element method software with the obtained predicted values of the simulation parameters under the different saturations as inputs, to obtain macro-mechanical parameters of the numerical model;
a comparison module, configured to compare the macro-mechanical parameters of the numerical model with the macro-mechanical parameters of the rock sample to obtain a comparison result;
an adjustment module, configured to finely adjust the predicted values of the simulation parameters under the different saturations according to the comparison result, until the obtained macro-mechanical parameters of the numerical model are the same as the macro-mechanical parameters of the actual rocks; and
a module for simulating rock working conditions under different saturations, configured to simulate rock working conditions under the different saturations based on the finely-adjusted predicted values of the simulation parameters under the different saturations, where the finely-adjusted predicted values of the simulation parameters under the different saturations are final values.

According to a third aspect, the present disclosure provides an electronic device, including a memory and a processor, where the memory is configured to store a computer program, and the processor runs the computer program to enable the electronic device to perform the above method for simulating water-induced rock strength deterioration based on a discrete element method.

According to a fourth aspect, the present disclosure provides a computer-readable storage medium, where a computer program is stored in the computer-readable storage medium, and when the computer program is executed by a processor, the above method for simulating water-induced rock strength deterioration based on a discrete element method is implemented.

According to the specific embodiments of the present disclosure, the present disclosure has the following technical effects.

Different from a conventional method in which it is tried to establish a relationship between simulation parameters and saturation, the present disclosure is based on the basic principle of the discrete element method that simulation parameters are constrained by macro-mechanical parameters of rocks; by constructing a relationship between simulation parameters and macro-mechanical parameters of rocks, macro-mechanical parameters of rocks with different saturations are inputted into the relationship, corresponding predicted simulation parameters are outputted and finely adjusted, and finally simulation parameters under the different saturations are determined, thereby implementing the simulation of water-induced rock strength deterioration. Therefore, the present disclosure solves the problem that the principle of a conventional method for simulating water-induced rock strength deterioration is unclear. Thanks to the remarkable advantages of the discrete element method in terms such as simulating nonlinear large deformation of rock mass, the present disclosure can truly reproduce mechanical behavior such as deformation and fracture of rocks with different saturation. Based on the basic principle of the above discrete element method, simulation parameters obtained by the present disclosure under different saturations are used as inputs, and outputted simulation macro-mechanical parameters have high consistency with test results. An example shows that an error between the simulation macro-mechanical parameters obtained by the present disclosure and the test results is below 0.74%, and a stress-strain curve and fracture mode are highly similar to those of the test results, proving that the method according to the present disclosure can truly simulate the process of water-induced rock strength deterioration. According to the present disclosure, the simulation parameters under the different saturations are determined by means of the relationship between the simulation parameters and the macro-mechanical parameters of rocks, which avoids taking the macro-mechanical parameters of rocks with the different saturations as a constraint, and the trial and error method is massively and repeatedly applied to calibrate the simulation parameters, thereby greatly saving calculation time and reducing memory occupation.

### BRIEF DESCRIPTION OF THE DRAWINGS

To describe the technical solutions in embodiments of the present disclosure or in the prior art more clearly, the accompanying drawings required in the embodiments are briefly described below. Apparently, the accompanying drawings in the following description show merely some embodiments of the present disclosure, and other accompanying drawings can be derived from these accompanying drawings by those of ordinary skill in the art without creative efforts.

FIGS. 1A-1B is a flowchart of a method for simulating water-induced rock strength deterioration based on a discrete element method according to the present disclosure;

FIG. 2 is a schematic diagram of numerical models of uniaxial compression simulation and Brazilian split simulation according to the present disclosure;

FIG. 3 is a schematic diagram of contact normal stiffness—macro Young's modulus parameter association according to the present disclosure;

FIG. 4 is a schematic diagram of contact tensile strength—Brazilian tensile strength parameter association according to the present disclosure;

FIG. 5 is a schematic diagram of contact cohesion and contact internal friction angle—uniaxial compressive strength parameter association according to the present disclosure;

FIG. 6 is a schematic diagram showing a comparison between macro-mechanical parameters obtained by tests and simulation according to the present disclosure; and

FIG. 7 is a schematic diagram showing a comparison between test and simulation results according to the present disclosure.

### DETAILED DESCRIPTION OF THE EMBODIMENTS

The technical solutions of the embodiments of the present disclosure are clearly and completely described below with reference to the accompanying drawings in the embodiments of the present disclosure. Apparently, the described embodiments are merely some rather than all of the embodiments of the present disclosure. All other embodiments obtained by those of ordinary skill in the art based on the embodiments of the present disclosure without creative efforts shall fall within the protection scope of the present disclosure.

An objective of the present disclosure is to provide a method and system for simulating water-induced rock strength deterioration based on a discrete element method, to implement numerical simulation representation of water-induced rock strength deterioration, and improve simulation precision and calculation efficiency.

To make the above objectives, features, and advantages of the present disclosure clearer and more comprehensible, the present disclosure will be further described in detail below with reference to the accompanying drawings and the specific implementations.

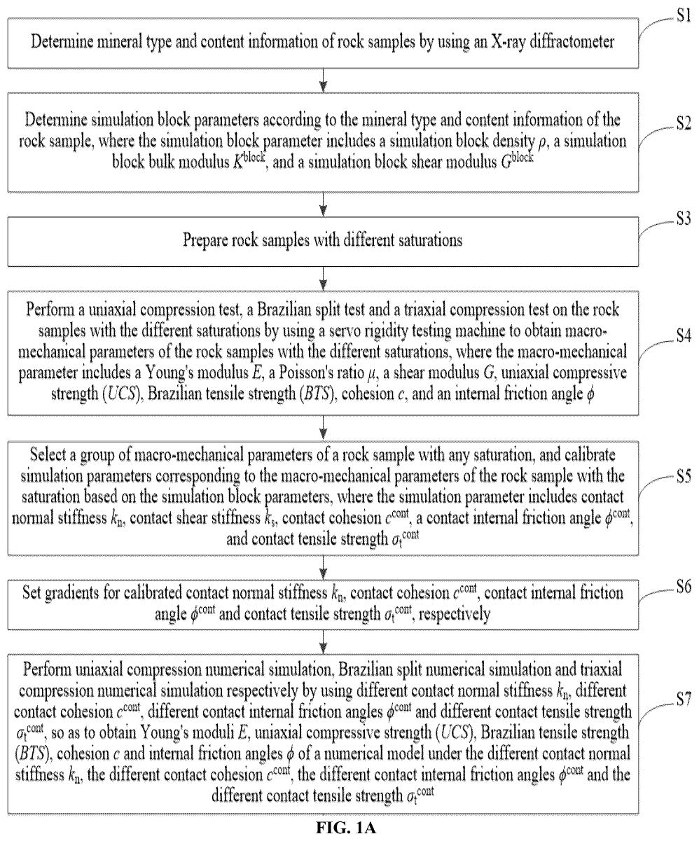

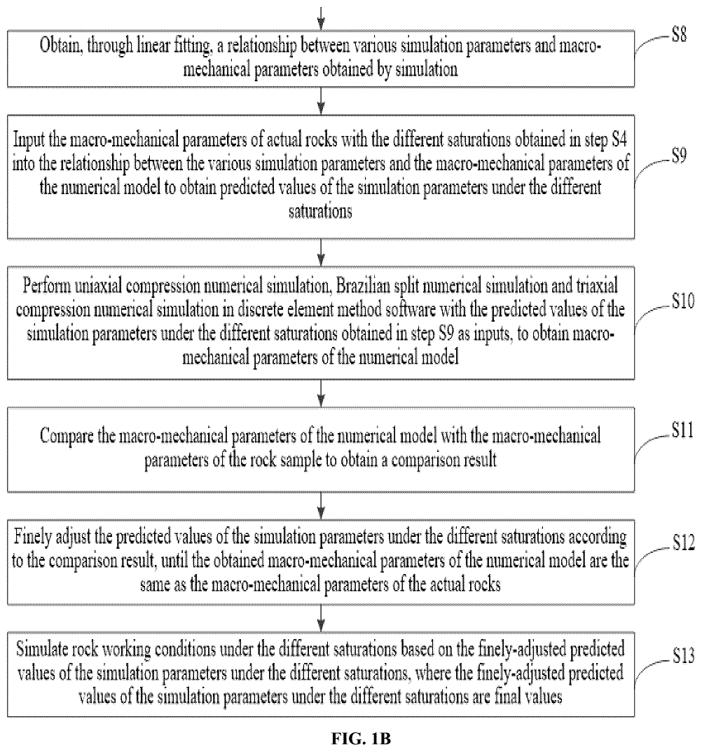

FIGS. 1A-1B show a flowchart of a method for simulating water-induced rock strength deterioration based on a discrete element method according to the present disclosure. As shown in FIG. 1A-1B, the simulation method according to the present disclosure includes the following steps.

S1: Determine mineral type and content information of rock samples by using an X-ray diffractometer.

S2: Determine simulation block parameters according to the mineral type and content information of the rock sample, where the simulation block parameter includes a simulation block density ρ, a simulation block bulk modulus K^{block}, and a simulation block shear modulus G^{block}.

In the discrete element method, mineral particles are often represented by simulation blocks.

S3: Prepare rock samples with different saturations.

Specifically, saturated rock samples are prepared according to international standards, dry rock samples are prepared by using a drying oven, and the dry rock samples absorb water by using a quality control method in a vacuum container, so as to obtain the rock samples with the different saturations.

S4: Perform a uniaxial compression test, a Brazilian split test and a triaxial compression test on the rock samples with the different saturations by using a servo rigidity testing machine to obtain macro-mechanical parameters of the rock samples with the different saturations, where the macro-mechanical parameter includes a Young's modulus E, a Poisson's ratio μ, a shear modulus G, uniaxial compressive strength (UCS), Brazilian tensile strength (BTS), cohesion c, and an internal friction angle ϕ.

For the test process, reference is made to People's Republic of China (PRC) industry standard Code for rock tests of hydroelectric and water conservancy engineering (SL264-2001) to obtain macro-mechanical parameters of rock samples with different saturations.

S5: Select a group of macro-mechanical parameters of a rock sample with any saturation, and calibrate simulation parameters corresponding to the macro-mechanical parameters of the rock sample with the saturation based on the simulation block parameters, where the simulation parameter includes contact normal stiffness kₙ, contact shear stiffness kₛ, contact cohesion c^{cont}, a contact internal friction angle ϕ^{cont}, and contact tensile strength σₜ^{cont}.

The simulation parameters corresponding to the macro-mechanical parameters of the sample with the saturation are calibrated by using a trial and error method in discrete element method software, specifically including the following steps.

S5.1: Input any group of simulation parameters (also referred to as contact parameters), including contact normal stiffness kₙ, contact shear stiffness kₛ, contact cohesion c^{cont}, a contact internal friction angle ϕ^{cont}, and contact tensile strength of σₜ^{cont}.

S5.2: Determine whether the contact normal stiffness and the contact shear stiffness are less than or equal to a preset threshold.

The preset threshold is:

$$10 max \frac{{K}^{block} + \frac{4}{3 {G}^{block}}}{Δ {z}_{min}}$$

where Δzₘᵢₙ represents a minimum width of adjacent elements in a vertical direction, max represents a maximum value of all elements contact-adjacent to each other, K^{block} represents a simulation block bulk modulus, and G^{block} represents a simulation block shear modulus (that is, several materials may exist in adjacent contact).

S5.3: If no, return to step S5.1.

S5.4: If yes, perform a next step.

S5.5: Determine whether a ratio of the contact shear stiffness to the contact normal stiffness is equal to a ratio of a sample shear modulus to a sample Young's modulus.

S5.6: If no, return to step S5.1.

S5.7: If yes, perform a next step.

S5.8: Perform the uniaxial compression numerical simulation in the discrete element method software, where dimension and boundary conditions of the numerical model are the same as those of uniaxially compressed samples and loading conditions.

S5.9: Determine whether the Young's modulus of the numerical model obtained by the uniaxial compression numerical simulation is equal to a test value.

S5.10: If no, return to step S5.1.

S5.11: If yes, determine values of the contact shear stiffness and the contact normal stiffness, still keep the values of the contact shear stiffness and the contact normal stiffness unchanged even after returning to step S5.1 in subsequent steps, and perform a next step.

S5.12: Perform the Brazilian split numerical simulation in the discrete element method software, where dimension and boundary conditions of the numerical model are the same as those of Brazilian split samples and loading conditions.

S5.13: Determine whether the Brazilian tensile strength of the numerical model obtained by the Brazilian split numerical simulation is equal to a test value.

S5.14: If no, return to step S5.1.

S5.15: If yes, determine a value of the contact tensile strength, still keep the value of the contact tensile strength unchanged even after returning to step S5.1 in subsequent steps, and perform a next step.

S5.16: Perform the uniaxial compression numerical simulation and the triaxial compression numerical simulation in the discrete element method software, where dimension and boundary conditions of the numerical model are the same as those of samples for the uniaxial compression test and the triaxial compression test and loading conditions.

S5.17: Determine whether the cohesion and the internal friction angle of the numerical model obtained by the uniaxial compression numerical simulation and the triaxial compression numerical simulation are equal to test values.

S5.18: If no, return to step S5.1.

S5.19: if yes, determine the contact cohesion and the contact internal friction angle, and end the trial and error method, thereby completing the calibration of the simulation parameters used to simulate mechanical behavior of samples under a selected saturation.

S6: Set gradients for calibrated contact normal stiffness kₙ, contact cohesion c^{cont}, contact internal friction angle ϕ^{cont} and contact tensile strength σₜ^{cont}, respectively.

A gradient setting direction should depend on the selected saturation, and theoretically the gradient should be set uniformly from 0 to an expected maximum.

S7: After the gradients are set, perform uniaxial compression numerical simulation, Brazilian split numerical simulation and triaxial compression numerical simulation respectively by using different contact normal stiffness kₙ, different contact cohesion c^{cont}, different contact internal friction angles ϕ^{cont} and different contact tensile strength σₜ^{cont}, where dimension and boundary conditions of the numerical model are the same as those of the test, so as to obtain Young's moduli F, uniaxial compressive strength (UCS), Brazilian tensile strength (BTS), contact cohesion c and contact internal friction angles ϕ of a numerical model under the different contact normal stiffness kₙ, the different contact cohesion c^{cont}, the different contact internal friction angles ϕ^{cont} and the different contact tensile strength σₜ^{cont}.

S8: Obtain, through linear fitting, a relationship between various simulation parameters and macro-mechanical parameters obtained by simulation.

The relationship specifically includes: a contact normal stiffness—Young's modulus relationship, a contact tensile strength—Brazilian tensile strength relationship, a contact cohesion—uniaxial compressive strength relationship, a contact cohesion-cohesion relationship, a contact internal friction angle—uniaxial compressive strength relationship, and a contact internal friction angle—internal friction angle relationship.

S9: Input the macro-mechanical parameters of actual rocks with the different saturations obtained in step S4 into the relationship between the various simulation parameters and the macro-mechanical parameters of the numerical model to obtain predicted values of the simulation parameters under the different saturations.

Specifically, the macro-mechanical parameters (Young's modulus, uniaxial compressive strength, Brazilian tensile strength, cohesion and internal friction angle) of the actual rocks with the different saturations obtained in step S4 are inputted into the above relationship (contact normal stiffness—Young's modulus, contact tensile strength—Brazilian tensile strength, contact cohesion—uniaxial compressive strength, contact cohesion-cohesion, contact internal friction angle—uniaxial compressive strength, and contact internal friction angle—internal friction angle) between the various simulation parameters and the macro-mechanical parameters of the numerical model to obtain predicted values of the simulation parameters (contact normal stiffness, contact tensile strength, contact cohesion and contact internal friction angle) under the different saturations.

S10: Perform uniaxial compression numerical simulation, Brazilian split numerical simulation and triaxial compression numerical simulation in discrete element method software with the predicted values of the simulation parameters (contact normal stiffness, contact tensile strength, contact cohesion and contact internal friction angle) under the different saturations obtained in step S9 as inputs, where the dimension and boundary conditions of the numerical model are the same as those of the test, to obtain macro-mechanical parameters of the numerical model.

S11: Compare the macro-mechanical parameters of the numerical model with the macro-mechanical parameters of the rock sample, including the Young's modulus, the uniaxial compressive strength, the Brazilian tensile strength, the cohesion and the internal friction angle, to obtain a comparison result.

S12: Finely adjust the predicted values of the simulation parameters under the different saturations according to the comparison result, until the obtained macro-mechanical parameters of the numerical model are the same as the macro-mechanical parameters of the actual rocks.

S13: Simulate rock working conditions under the different saturations based on the finely-adjusted predicted values of the simulation parameters under the different saturations, where the finely-adjusted predicted values of the simulation parameters under the different saturations are final values.

Specifically, according to the comparison result, the predicted simulation parameters (contact normal stiffness, contact tensile strength, contact cohesion and contact internal friction angle) under the different saturations are finely adjusted. Considering the heterogeneity of rocks, the fine adjustment range is suggested to be within a 90-100% prediction band and confidence band of a linear fitting curve. Then uniaxial compression numerical simulation, Brazilian split numerical simulation and triaxial compression numerical simulation are repeated, and the dimension and boundary conditions of the numerical model are the same as those of the test, until the obtained macro-mechanical parameters of the numerical model are the same as the macro-mechanical parameters of the actual rocks, including the Young's modulus, the uniaxial compressive strength, the Brazilian tensile strength, the cohesion and the internal friction angle. Finally simulation parameters (contact normal stiffness, contact tensile strength, contact cohesion and contact internal friction angle) corresponding to different saturations can be determined, so that rock working conditions can be simulated under different saturations. For example, the simulation parameters corresponding to the different saturations are obtained. For example, if a saturation of 10% corresponds to a macro parameter 1 of and a simulation parameter a of rocks, and a saturation of 50% corresponds to a macro parameter 2 and a simulation parameter b of rocks, a change from the macro parameter 1 to the macro parameter 2 of rocks can be expressed by a change from the simulation parameter a to the simulation parameter b, and then the change from the simulation parameter a to the simulation parameter b can be applied in subsequent applications, such as how to simulate the change from the saturation of 10% to the saturation of 50% when rainfall infiltration into rock mass causes landslide.

The present disclosure is further described below with a specific embodiment.

Red sandstone in Yichang, Hubei Province was selected as a research prototype. Mineral type, content and dimension information of the sandstone was determined by means of an X-ray diffraction analysis method, and thus simulation block parameters, including a block density, a block bulk modulus and a block shear modulus, were determined.

A water absorption test was performed on rock samples, to obtain red sandstone samples with different saturations (9.23%, 30%, 60%, 90% and 100%).

A uniaxial compression test and a Brazilian split test were performed on the rock samples with the different saturations by using a WAW-300 electro-hydraulic servo rigidity testing machine to obtain macro-mechanical parameters of each group of rock samples, including a Young's modulus, a Poisson's ratio, uniaxial compressive strength, and Brazilian tensile strength.

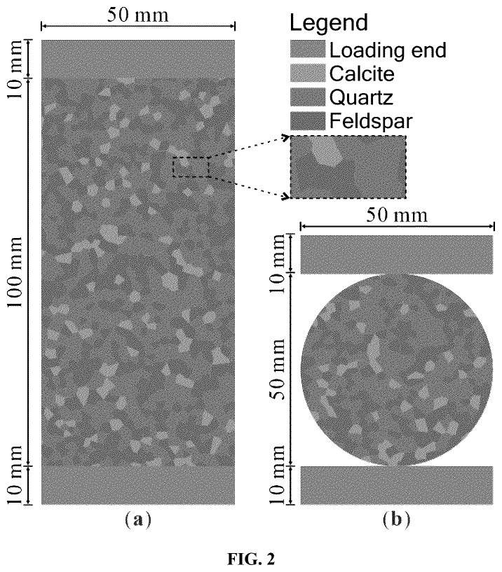

Discrete element method software, universal distinct element code (UDEC), was used to model the samples, macro-mechanical parameters of a sample with a natural saturation (9.23%) were selected as constraints to perform uniaxial compression numerical simulation and Brazilian split numerical simulation (see FIG. 2), and simulation parameters were continuously adjusted by using a trial and error method until macro-mechanical parameters obtained by the simulation were consistent with test results.

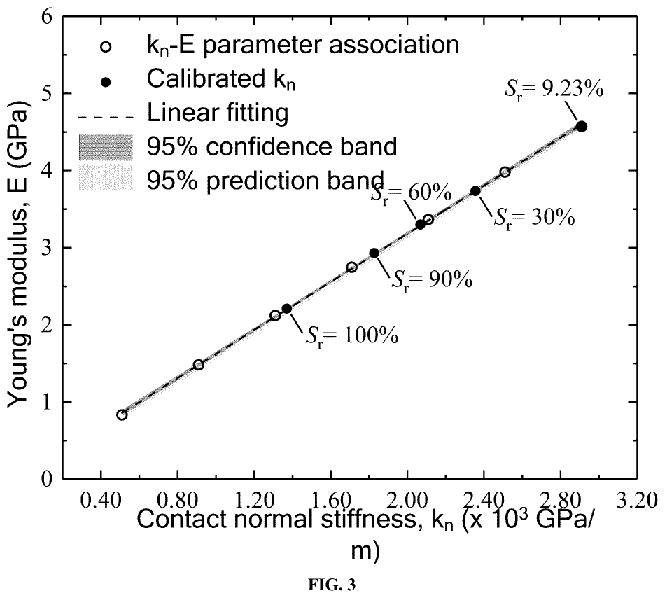

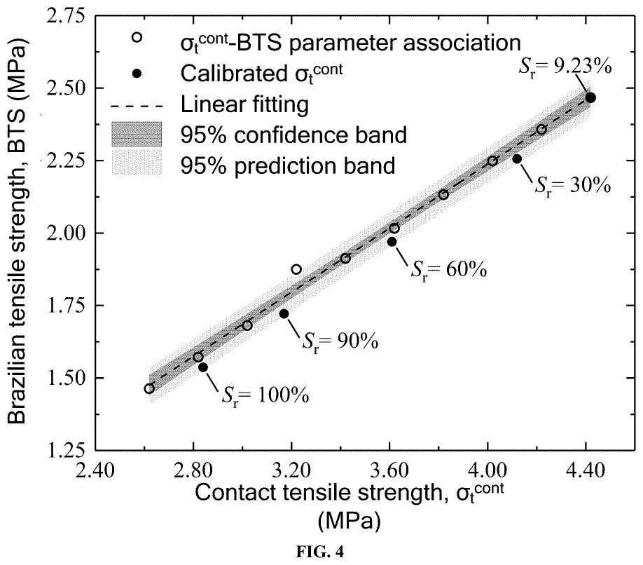

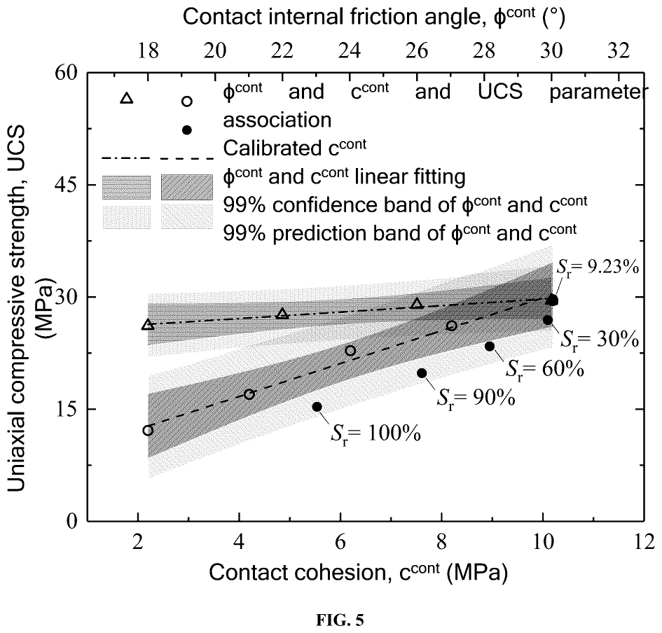

Based on the simulation parameters corresponding to the above natural saturation, contact normal stiffness, contact cohesion, a contact internal friction angle and contact tensile strength were taken as independent variables, and reasonable gradients were set to perform uniaxial compression numerical simulation and Brazilian split numerical simulation, to obtain a contact normal stiffness—macroscopic Young's modulus relationship (as shown in FIG. 3), a contact tensile strength—Brazilian tensile strength relationship (as shown in FIG. 4), a contact cohesion—uniaxial compressive strength relationship (as shown in FIG. 5) and a contact internal friction angle—uniaxial compressive strength relationship (as shown in FIG. 5).

Young's moduli, Brazilian tensile strength and uniaxial compressive strength obtained under different saturations by the test were inputted into the relationship between the above various simulation parameters and the simulation macro-mechanical parameters, to obtain predicted contact normal stiffness, predicted contact tensile strength, and predicted contact cohesion. Because an absolute value of a contact internal friction angle—uniaxial compressive strength slope was small, a predicted contact internal friction angle was negative; in addition, existing research shows that the contact internal friction angle mainly affects an internal friction angle, and the internal friction angle is very unlikely to be affected by water-induced deterioration, so the contact internal friction angle was set to a constant value.

Each group of predicted simulation parameters obtained was inputted to the UDEC for uniaxial compression numerical simulation and Brazilian split numerical simulation, to obtain macro-mechanical parameters of the model corresponding to each group of predicted simulation parameters.

The macro-mechanical parameters obtained by tests and simulation, including the Young's modulus, Brazilian tensile strength and uniaxial compressive strength, were compared. The error of each Young's modulus obtained from the tests and simulation corresponding to the five groups of saturations was below 0.69%, indicating that the predicted contact normal stiffness did not need to be adjusted, and could be determined as final contact normal stiffness (as shown by solid dots in FIG. 3). Compared with the test results, the Brazilian tensile strength obtained by simulation was excessively low. After fine adjustment of the predicted contact tensile strength, the error of the Brazilian tensile strength obtained from the tests and simulation corresponding to the five groups of saturations was below 0.23%, and the finely-adjusted contact tensile strength (as shown by solid dots in FIG. 4) was within a 95% prediction band of the contact tensile strength—Brazilian tensile strength linear relationship, and could be determined as final contact tensile strength. The uniaxial compressive strength obtained by simulation was slightly lower than the test value, and the predicted contact cohesion was finely adjusted. The error of the uniaxial compressive strength obtained by the tests and simulation corresponding to five groups of saturations was below 0.74%, and the finely-adjusted contact cohesion (as shown by solid dots in FIG. 5) was within a 99% prediction band of the contact cohesion—uniaxial compressive strength linear relationship, and could be determined as final contact cohesion.

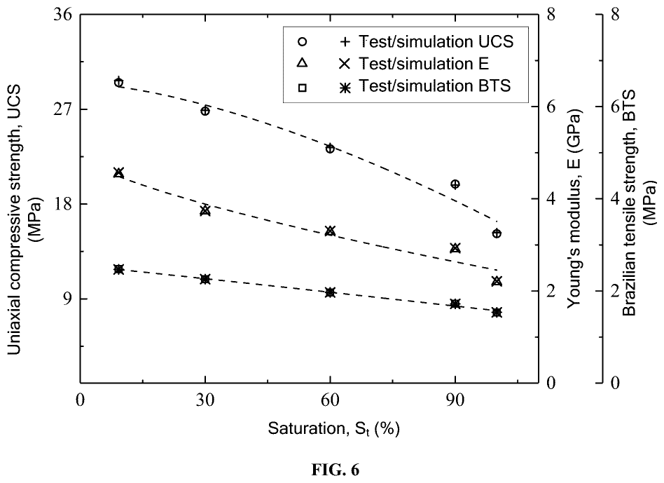

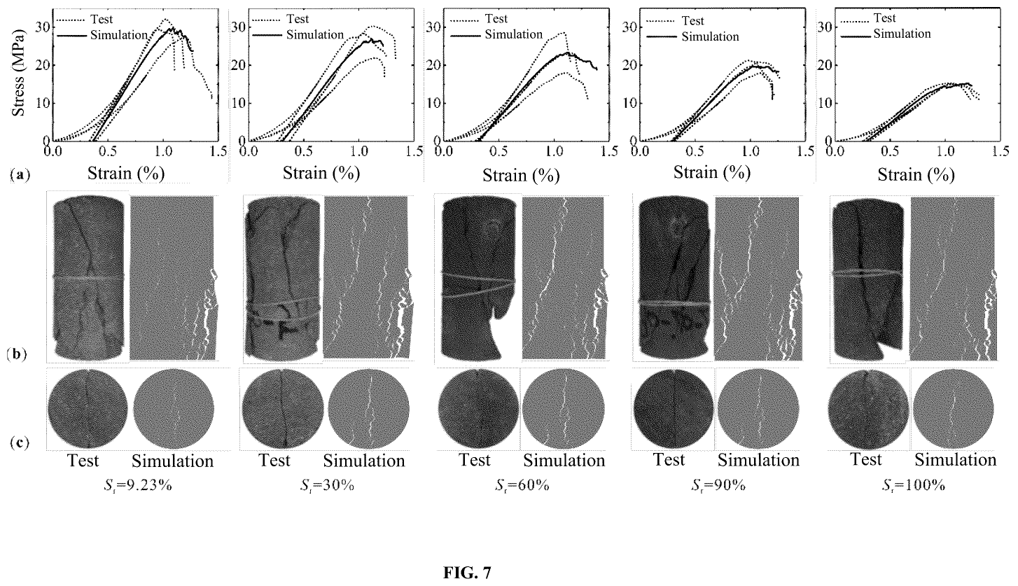

Therefore, the contact normal stiffness, the contact cohesion, the contact internal friction angles and the contact tensile strength corresponding to the five groups of saturations were determined. The above simulation parameters were inputted to the UDEC for uniaxial compression numerical simulation and Brazilian split numerical simulation, and simulation results were compared with the test results. FIG. 6 shows a comparison of three types of macro-mechanical parameters, that is, uniaxial compressive strength, a Young's modulus and Brazilian tensile strength, obtained by simulation and tests. A part a in FIG. 7 shows a comparison between axial stress-strain curves obtained by simulation and tests; a part b in FIG. 7 shows a comparison of fracture modes under uniaxial compression obtained by simulation and tests; and a part c in FIG. 7 shows a comparison between fracture modes under Brazilian split obtained by simulation and tests. It can be seen that the present disclosure implements simulation of water-induced rock strength deterioration.

Based on the above method of the present disclosure, the present disclosure additionally provides a system for simulating water-induced rock strength deterioration based on a discrete element method, including:
a module for determining mineral type and content information of rock samples, configured to determine mineral type and content information of rock samples by using an X-ray diffractometer;
a simulation block parameter determining module, configured to determine simulation block parameters according to the mineral type and content information of the rock sample, where the simulation block parameter includes a simulation block density ρ, a simulation block bulk modulus K^{block}, and a simulation block shear modulus G^{block};
a module for preparing rock samples with different saturations, configured to prepare rock samples with different saturations;
a module for determining macro-mechanical parameters of rock samples with different saturations, configured to perform a uniaxial compression test, a Brazilian split test and a triaxial compression test on the rock samples with the different saturations by using a servo rigidity testing machine to obtain macro-mechanical parameters of the rock samples with the different saturations, where the macro-mechanical parameter includes a Young's modulus E, a Poisson's ratio μ, a shear modulus G, uniaxial compressive strength (UCS), Brazilian tensile strength (BTS), cohesion c, and an internal friction angle ϕ;
a calibration module, configured to select a group of macro-mechanical parameters of a rock sample with any saturation, and calibrate simulation parameters corresponding to the macro-mechanical parameters of the rock sample with the saturation based on the simulation block parameters, where the simulation parameter includes contact normal stiffness kₙ, contact shear stiffness kₛ, contact cohesion c^{cont}, a contact internal friction angle ϕ^{cont}, and contact tensile strength σₜ^{cont},
a gradient setting module, configured to set gradients for calibrated contact normal stiffness kₙ, contact cohesion c^{cont}, contact internal friction angle ϕ^{cont} and contact tensile strength σₜ^{cont}, respectively;
a first numerical simulation module, configured to perform uniaxial compression numerical simulation, Brazilian split numerical simulation and triaxial compression numerical simulation respectively by using different contact normal stiffness kₙ, different contact cohesion c^{cont}, different contact internal friction angles ϕ^{cont} and different contact tensile strength σₜ^{cont}, so as to obtain Young's moduli F, uniaxial compressive strength (IC'S), Brazilian tensile strength (BTS), cohesion c and internal friction angles ϕ of a numerical model under the different contact normal stiffness kₙ, the different contact cohesion c^{cont}, the different contact internal friction angles ϕ^{cont} and the different contact tensile strength σₜ^{cont};
a linear fitting module, configured to obtain, through linear fitting, a relationship between various simulation parameters and macro-mechanical parameters obtained by simulation;
a prediction module, configured to input the macro-mechanical parameters of actual rocks with the different saturations into the relationship between the various simulation parameters and the macro-mechanical parameters of the numerical model to obtain predicted values of the simulation parameters under the different saturations;
a second numerical simulation module, configured to perform uniaxial compression numerical simulation, Brazilian split numerical simulation and triaxial compression numerical simulation in discrete element method software with the obtained predicted values of the simulation parameters under the different saturations as inputs, to obtain macro-mechanical parameters of the numerical model;
a comparison module, configured to compare the macro-mechanical parameters of the numerical model with the macro-mechanical parameters of the rock sample to obtain a comparison result;
an adjustment module, configured to finely adjust the predicted values of the simulation parameters under the different saturations according to the comparison result, until the obtained macro-mechanical parameters of the numerical model are the same as the macro-mechanical parameters of the actual rocks; and
a module for simulating rock working conditions under different saturations, configured to simulate rock working conditions under the different saturations based on the finely-adjusted predicted values of the simulation parameters under the different saturations, where the finely-adjusted predicted values of the simulation parameters under the different saturations are final values.

The present disclosure further provides an electronic device, including a memory and a processor, where the memory is configured to store a computer program, and the processor runs the computer program to enable the electronic device to perform the above method for simulating water-induced rock strength deterioration based on a discrete element method.

The present disclosure further provides a computer-readable storage medium, where a computer program is stored in the computer-readable storage medium, and when the computer program is executed by a processor, the above method for simulating water-induced rock strength deterioration based on a discrete element method is implemented.

Embodiments of the description are described in a progressive manner, each embodiment focuses on the difference from other embodiments, and for the same and similar parts between the embodiments, reference may be made to each other. Since the system disclosed in an embodiment corresponds to the method disclosed in another embodiment, the description is relatively simple, and reference may be made to the method description.

Specific examples are used herein to explain the principles and implementations of the present disclosure. The foregoing description of the embodiments is merely intended to help understand the method of the present disclosure and its core ideas; besides, changes may be made by those of ordinary skill in the art to specific implementations and the scope of application in accordance with the ideas of the present disclosure. In conclusion, the content of the description shall not be construed as limitations to the present disclosure.

1. A method for preventing a rock mass geological disaster, comprising:
S1: determining a mineral type and content information of a raw rock sample of a rock mass by using an X-ray diffractometer;
S2: determining simulation block parameters according to the mineral type and content information of the raw rock sample, wherein the simulation block parameters comprise a simulation block density ρ, a simulation block bulk modulus K^{block}, and a simulation block shear modulus G^{block};
S3: preparing a plurality of rock samples with different saturations based on the raw rock sample;
S4: performing a uniaxial compression test, a Brazilian split test and a triaxial compression test on the plurality of rock samples with the different saturations by using a servo rigidity testing machine to obtain macro-mechanical parameters of the plurality of rock samples with the different saturations, wherein the macro-mechanical parameters comprise a Young's modulus E, a Poisson's ratio μ, a shear modulus G, uniaxial compressive strength (UCS), Brazilian tensile strength (BTS), cohesion c, and an internal friction angle ϕ;
S5: selecting a group of macro-mechanical parameters of a rock sample of the plurality of rock samples, and calibrating simulation parameters corresponding to the macro-mechanical parameters of the rock sample based on the simulation block parameters, wherein the simulation parameters comprise contact normal stiffness kₙ, contact shear stiffness kₛ, contact cohesion c^{cont}, a contact internal friction angle ϕ^{cont}, and contact tensile strength σₜ^{cont};
S6: setting gradients for the calibrated contact normal stiffness kₙ, contact cohesion c^{cont}, contact internal friction angle ϕ^{cont} and contact tensile strength σₜ^{cont}, respectively;
S7: performing uniaxial compression numerical simulation, Brazilian split numerical simulation and triaxial compression numerical simulation respectively by using different contact normal stiffness kₙ, different contact cohesion c^{cont}, different contact internal friction angles ϕ^{cont} and different contact tensile strength σₜ^{cont}, so as to obtain Young's moduli E, uniaxial compressive strength (UCS), Brazilian tensile strength (BTS), cohesion c and internal friction angles ϕ^{cont} of a numerical model under the different contact normal stiffness kₙ, the different contact cohesion c^{cont}, the different contact internal friction angles ϕ and the different contact tensile strength σₜ^{cont};
S8: obtaining, through linear fitting, a relationship between the simulation parameters in step S5 and the simulated macro-mechanical parameters in step S7;
S9: inputting the macro-mechanical parameters of the plurality of rock samples with the different saturations obtained in step S4 into the relationship between the simulation parameters and the simulated macro-mechanical parameters in step S8 to obtain predicted values of the simulation parameters under the different saturations;
S10: performing uniaxial compression numerical simulation, Brazilian split numerical simulation and triaxial compression numerical simulation using a discrete element method software with the predicted values of the simulation parameters under the different saturations obtained in step S9 as inputs, to obtain macro-mechanical parameters of the numerical model;
S11: comparing the macro-mechanical parameters of the numerical model in step S10 with the macro-mechanical parameters of the plurality of rock samples in step S4 to obtain a comparison result;
S12: finely adjusting the predicted values of the simulation parameters under the different saturations according to the comparison result, until the obtained macro-mechanical parameters of the numerical model are the same as the macro-mechanical parameters of the plurality of rock samples;
S13: simulating rock working conditions under the different saturations based on the finely-adjusted predicted values of the simulation parameters under the different saturations, wherein the finely-adjusted predicted values of the simulation parameters under the different saturations are final values; and
S14: preventing the rock mass geological disaster by reinforcing the rock mass based on the simulated rock working conditions, wherein reinforcing the rock mass comprises at least one of coating a surface of the rock mass using mortar to prevent rainfall infiltration, building a gutter along a boundary of the rock mass such that surface water is drained, building a drainage ditch in a rock mass area to reduce the rainfall infiltration, using prestressed anchors or a reinforced concrete anchoring pile, using rows of anti-slip piles, or using cementation grouting.

2. The method according to claim 1, wherein the selecting the group of macro-mechanical parameters of the rock sample of the plurality of rock samples, and calibrating the simulation parameters corresponding to the macro-mechanical parameters of the rock sample based on the simulation block parameters comprises the following steps:
S5.1: inputting any group of simulation parameters, comprising contact normal stiffness kₙ, contact shear stiffness kₛ, contact cohesion c^{cont}, a contact internal friction angle ϕ^{cont}, and contact tensile strength σₜ^{cont};
S5.2: determining whether the contact normal stiffness and the contact shear stiffness are less than or equal to a preset threshold;
S5.3: if no, returning to step S5.1;
S5.4: if yes, performing a next step;
S5.5: determining whether a ratio of the contact shear stiffness to the contact normal stiffness is equal to a ratio of a sample shear modulus to a sample Young's modulus;
S5.6: if no, returning to step S5.1;
S5.7: if yes, performing a next step;
S5.8: performing the uniaxial compression numerical simulation in the discrete element method software, wherein dimension and boundary conditions of the numerical model are the same as those of uniaxially compressed samples and loading conditions;
S5.9: determining whether the Young's modulus of the numerical model obtained by the uniaxial compression numerical simulation is equal to a test value;
S5.10: if no, returning to step S5.1;
S5.11: if yes, determining values of the contact shear stiffness and the contact normal stiffness, still keeping the values of the contact shear stiffness and the contact normal stiffness unchanged even after returning to step S5.1 in subsequent steps, and performing a next step;
S5.12: performing the Brazilian split numerical simulation in the discrete element method software, wherein dimension and boundary conditions of the numerical model are the same as those of Brazilian split samples and loading conditions;
S5.13: determining whether the Brazilian tensile strength of the numerical model obtained by the Brazilian split numerical simulation is equal to a test value;
S5.14: if no, returning to step S5.1;
S5.15: if yes, determining a value of the contact tensile strength, still keeping the value of the contact tensile strength unchanged even after returning to step S5.1 in subsequent steps, and performing a next step;
S5.16: performing the uniaxial compression numerical simulation and the triaxial compression numerical simulation in the discrete element method software, wherein dimension and boundary conditions of the numerical model are the same as those of samples for the uniaxial compression test and the triaxial compression test and loading conditions;
S5.17: determining whether the cohesion and the internal friction angle of the numerical model obtained by the uniaxial compression numerical simulation and the triaxial compression numerical simulation are equal to test values;
S5.18: if no, returning to step S5.1; and
S5.19: if yes, determining the contact cohesion and the contact internal friction angle, and ending a trial and error method, thereby completing the calibration of the simulation parameters used to simulate mechanical behavior of samples under a selected saturation.

3. The method according to claim 1, wherein the preparing the plurality of rock samples with different saturations based on the raw rock sample comprises:
preparing saturated rock samples according to international standards, preparing dry rock samples by using a drying oven, and causing the dry rock samples to absorb water by using a quality control method in a vacuum container, so as to obtain the plurality of rock samples with the different saturations.

4. The method according to claim 1, wherein a simulation block represents mineral particles.

5. The method according to claim 2, wherein an expression of the preset threshold is as follows:
$$10 max \frac{{K}^{block} + \frac{4}{3 {G}^{block}}}{Δ {z}_{min}}$$
wherein Δzₘᵢₙ represents a minimum width of adjacent elements in a vertical direction, max represents a maximum value of all elements contact-adjacent to each other, K^{block} represents a simulation block bulk modulus, and G^{block} represents a simulation block shear modulus.

6. The method according to claim 1, wherein the relationship between the simulation parameters in step S5 and the simulated macro-mechanical parameters in step S7 comprises: a contact normal stiffness—Young's modulus relationship, a contact tensile strength—Brazilian tensile strength relationship, a contact cohesion—uniaxial compressive strength relationship, a contact cohesion-cohesion relationship, a contact internal friction angle—uniaxial compressive strength relationship, and a contact internal friction angle—internal friction angle relationship.

7. A system for preventing a rock mass geological disaster, comprising:
an X-ray diffractometer, configured to determine a mineral type and content information of a raw rock sample of a rock mass;
a servo rigidity testing machine, configured to perform a uniaxial compression test, a Brazilian split test and a triaxial compression test on a plurality of rock samples with different saturations prepared based on the raw rock sample to obtain macro-mechanical parameters of the plurality of rock samples with the different saturations, wherein the macro-mechanical parameters comprise a Young's modulus E, a Poisson's ratio μ, a shear modulus G, uniaxial compressive strength (UCS), Brazilian tensile strength (BTS), cohesion c, and an internal friction angle ϕ; and
an electronic device, comprising a processor and a memory, wherein the memory is configured to store a computer program that, when executed, causes the processor to:
determine simulation block parameters according to the mineral type and content information of the raw rock sample, wherein the simulation block parameters comprise a simulation block density ρ, a simulation block bulk modulus K^{block}, and a simulation block shear modulus G^{block};
select a group of macro-mechanical parameters of a rock sample of the plurality of rock samples, and calibrate simulation parameters corresponding to the macro-mechanical parameters of the rock sample based on the simulation block parameters, wherein the simulation parameters comprise contact normal stiffness kₙ, contact shear stiffness kₛ, contact cohesion c^{cont}, a contact internal friction angle ϕ^{cont}, and contact tensile strength σₜ^{cont};
set gradients for the calibrated contact normal stiffness kₙ, contact cohesion c^{cont}, contact internal friction angle ϕ^{cont} and contact tensile strength σₜ^{cont}, respectively;
perform uniaxial compression numerical simulation, Brazilian split numerical simulation and triaxial compression numerical simulation respectively by using different contact normal stiffness kₙ, different contact cohesion c^{cont}, different contact internal friction angles ϕ and different contact tensile strength σₜ^{cont}, so as to obtain Young's moduli E, uniaxial compressive strength (UCS), Brazilian tensile strength (BTS), cohesion c and internal friction angles of a numerical model under the different contact normal stiffness kₙ, the different contact cohesion c^{cont}, the different contact internal friction angles ϕ^{cont} and the different contact tensile strength σₜ^{cont};
obtain, through linear fitting, a relationship between the simulation parameters and the simulated macro-mechanical parameters;
input the macro-mechanical parameters of the plurality of rock samples with the different saturations into the relationship between the simulation parameters and the simulated macro-mechanical parameters of the numerical model to obtain predicted values of the simulation parameters under the different saturations;
perform uniaxial compression numerical simulation, Brazilian split numerical simulation and triaxial compression numerical simulation using a discrete element method software with the obtained predicted values of the simulation parameters under the different saturations as inputs, to obtain macro-mechanical parameters of the numerical model;
compare the macro-mechanical parameters of the numerical model with the macro-mechanical parameters of the plurality of rock samples to obtain a comparison result;
finely adjust the predicted values of the simulation parameters under the different saturations according to the comparison result, until the obtained macro-mechanical parameters of the numerical model are the same as the macro-mechanical parameters of the plurality of rock samples;
simulate rock working conditions under the different saturations based on the finely-adjusted predicted values of the simulation parameters under the different saturations, wherein the finely-adjusted predicted values of the simulation parameters under the different saturations are final values; and
prevent the rock mass geological disaster by reinforcing the rock mass based on the simulated rock working conditions, wherein reinforcing the rock mass comprises at least one of coating a surface of the rock mass using mortar to prevent rainfall infiltration, building a gutter along a boundary of the rock mass such that surface water is drained, building a drainage ditch in a rock mass area to reduce the rainfall infiltration, using prestressed anchors or a reinforced concrete anchoring pile, using rows of anti-slip piles, or using cementation grouting.

8. An electronic device, comprising a memory and a processor, wherein the memory is configured to store a computer program that, when executed, causes the processor to perform the method according to claim 1.

9. The electronic device according to claim 8, wherein the selecting the group of macro-mechanical parameters of the rock sample of the plurality of rock samples, and calibrating the simulation parameters corresponding to the macro-mechanical parameters of the rock sample based on the simulation block parameters comprises:
S5.1: inputting any group of simulation parameters, comprising contact normal stiffness kₙ, contact shear stiffness kₛ, contact cohesion c^{cont}, a contact internal friction angle ϕ^{cont}, and contact tensile strength σₜ^{cont};
S5.2: determining whether the contact normal stiffness and the contact shear stiffness are less than or equal to a preset threshold;
S5.3: if no, returning to step S5.1;
S5.4: if yes, performing a next step;
S5.5: determining whether a ratio of the contact shear stiffness to the contact normal stiffness is equal to a ratio of a sample shear modulus to a sample Young's modulus;
S5.6: if no, returning to step S5.1;
S5.7: if yes, performing a next step;
S5.8: performing the uniaxial compression numerical simulation in the discrete element method software, wherein dimension and boundary conditions of the numerical model are the same as those of uniaxially compressed samples and loading conditions;
S5.9: determining whether the Young's modulus of the numerical model obtained by the uniaxial compression numerical simulation is equal to a test value;
S5.10: if no, returning to step S5.1;
S5.11: if yes, determining values of the contact shear stiffness and the contact normal stiffness, still keeping the values of the contact shear stiffness and the contact normal stiffness unchanged even after returning to step S5.1 in subsequent steps, and performing a next step;
S5.12: performing the Brazilian split numerical simulation in the discrete element method software, wherein dimension and boundary conditions of the numerical model are the same as those of Brazilian split samples and loading conditions;
S5.13: determining whether the Brazilian tensile strength of the numerical model obtained by the Brazilian split numerical simulation is equal to a test value;
S5.14: if no, returning to step S5.1;
S5.15: if yes, determining a value of the contact tensile strength, still keeping the value of the contact tensile strength unchanged even after returning to step S5.1 in subsequent steps, and performing a next step;
S5.16: performing the uniaxial compression numerical simulation and the triaxial compression numerical simulation in the discrete element method software, wherein dimension and boundary conditions of the numerical model are the same as those of samples for the uniaxial compression test and the triaxial compression test and loading conditions;
S5.17: determining whether the cohesion and the internal friction angle of the numerical model obtained by the uniaxial compression numerical simulation and the triaxial compression numerical simulation are equal to test values;
S5.18: if no, returning to step S5.1; and
S5.19: if yes, determining the contact cohesion and the contact internal friction angle, and ending a trial and error method, thereby completing the calibration of the simulation parameters used to simulate mechanical behavior of samples under a selected saturation.

10. The electronic device according to claim 8, wherein the preparing the plurality of rock samples with different saturations based on the raw rock sample comprises:
preparing saturated rock samples according to international standards, preparing dry rock samples by using a drying oven, and causing the dry rock samples to absorb water by using a quality control method in a vacuum container, so as to obtain the plurality of rock samples with the different saturations.

11. The electronic device according to claim 8, wherein a simulation block represents mineral particles.

12. The electronic device according to claim 9, wherein an expression of the preset threshold is as follows:
$$10 max \frac{{K}^{block} + \frac{4}{3 {G}^{block}}}{Δ {z}_{min}}$$
wherein Δzₘᵢₙ represents a minimum width of adjacent elements in a vertical direction, max represents a maximum value of all elements contact-adjacent to each other, K^{block} represents a simulation block bulk modulus, and G^{block} represents a simulation block shear modulus.

13. The electronic device according to claim 8, wherein the relationship between the various simulation parameters in step S5 and the simulated macro-mechanical parameters in step S7 comprises: a contact normal stiffness—Young's modulus relationship, a contact tensile strength—Brazilian tensile strength relationship, a contact cohesion—uniaxial compressive strength relationship, a contact cohesion-cohesion relationship, a contact internal friction angle—uniaxial compressive strength relationship, and a contact internal friction angle—internal friction angle relationship.

14. A non-transitory computer-readable storage medium, wherein a computer program is stored on the non-transitory computer-readable storage medium, and when the computer program is executed by a processor, the method according to claim 1 is implemented.

15. The non-transitory computer-readable storage medium according to claim 14, wherein the selecting the group of macro-mechanical parameters of the rock sample of the plurality of rock samples, and calibrating the simulation parameters corresponding to the macro-mechanical parameters of the rock sample based on the simulation block parameters comprises the following steps:
S5.1: inputting any group of simulation parameters, comprising contact normal stiffness kₙ, contact shear stiffness kₛ, contact cohesion c^{cont}, a contact internal friction angle ϕ^{cont}, and contact tensile strength σₜ^{cont};
S5.2: determining whether the contact normal stiffness and the contact shear stiffness are less than or equal to a preset threshold;
S5.3: if no, returning to step S5.1;
S5.4: if yes, performing a next step;
S5.5: determining whether a ratio of the contact shear stiffness to the contact normal stiffness is equal to a ratio of a sample shear modulus to a sample Young's modulus;
S5.6: if no, returning to step S5.1;
S5.7: if yes, performing a next step;
S5.8: performing the uniaxial compression numerical simulation in the discrete element method software, wherein dimension and boundary conditions of the numerical model are the same as those of uniaxially compressed samples and loading conditions;
S5.9: determining whether the Young's modulus of the numerical model obtained by the uniaxial compression numerical simulation is equal to a test value;
S5.10: if no, returning to step S5.1;
S5.11: if yes, determining values of the contact shear stiffness and the contact normal stiffness, still keeping the values of the contact shear stiffness and the contact normal stiffness unchanged even after returning to step S5.1 in subsequent steps, and performing a next step;
S5.12: performing the Brazilian split numerical simulation in the discrete element method software, wherein dimension and boundary conditions of the numerical model are the same as those of Brazilian split samples and loading conditions;
S5.13: determining whether the Brazilian tensile strength of the numerical model obtained by the Brazilian split numerical simulation is equal to a test value;
S5.14: if no, returning to step S5.1;
S5.15: if yes, determining a value of the contact tensile strength, still keeping the value of the contact tensile strength unchanged even after returning to step S5.1 in subsequent steps, and performing a next step;
S5.16: performing the uniaxial compression numerical simulation and the triaxial compression numerical simulation in the discrete element method software, wherein dimension and boundary conditions of the numerical model are the same as those of samples for the uniaxial compression test and the triaxial compression test and loading conditions;
S5.17: determining whether the cohesion and the internal friction angle of the numerical model obtained by the uniaxial compression numerical simulation and the triaxial compression numerical simulation are equal to test values;
S5.18: if no, returning to step S5.1; and
S5.19: if yes, determining the contact cohesion and the contact internal friction angle, and ending a trial and error method, thereby completing the calibration of the simulation parameters used to simulate mechanical behavior of samples under a selected saturation.

16. The non-transitory computer-readable storage medium according to claim 14, wherein the preparing the plurality of rock samples with different based on the raw rock sample saturations comprises:
preparing saturated rock samples according to international standards, preparing dry rock samples by using a drying oven, and causing the dry rock samples to absorb water by using a quality control method in a vacuum container, so as to obtain the rock samples with the different saturations.

17. The non-transitory computer-readable storage medium according to claim 14, wherein a simulation block represents mineral particles.

18. The non-transitory computer-readable storage medium according to claim 15, wherein an expression of the preset threshold is as follows:
$$10 max \frac{{K}^{block} + \frac{4}{3 {G}^{block}}}{Δ {z}_{min}}$$
wherein Δzₘᵢₙ represents a minimum width of adjacent elements in a vertical direction, max represents a maximum value of all elements contact-adjacent to each other, K^{block} represents a simulation block bulk modulus, and G^{block} represents a simulation block shear modulus.

19. The non-transitory computer-readable storage medium according to claim 14, wherein the relationship between the simulation parameters in step S5 and the simulated macro-mechanical parameters in step S7 comprises: a contact normal stiffness—Young's modulus relationship, a contact tensile strength—Brazilian tensile strength relationship, a contact cohesion—uniaxial compressive strength relationship, a contact cohesion—cohesion relationship, a contact internal friction angle—uniaxial compressive strength relationship, and a contact internal friction angle—internal friction angle relationship.
